(19) United States
(12) Patent Application Publication
(10) Pub. No.: US 2024/0164097 A1
(43) Pub. Date: May 16, 2024

(54) THREE-DIMENSIONAL MEMORY, FABRICATING METHOD THEREOF AND MEMORY SYSTEM

(71) Applicant: Yangtze Memory Technologies Co., Ltd., Wuhan (CN)

(72) Inventors: Jianquan JIA, Wuhan (CN); Weiming CHEN, Wuhan (CN); Weiwei CHU, Wuhan (CN); Junbao WANG, Wuhan (CN); Kaiwei LI, Wuhan (CN); Wenhao XIONG, Wuhan (CN); Lei JIN, Wuhan (CN)

(73) Assignee: Yangtze Memory Technologies Co., Ltd., Wuhan (CN)

(21) Appl. No.: 18/090,882

(22) Filed: Dec. 29, 2022

(30) Foreign Application Priority Data
Nov. 10, 2022 (CN) 2022114099483

(51) Int. Cl. H10B 43/27; H10B 41/27

(52) U.S. Cl. CPC H01L 27/11582; H01L 27/11556

(57) ABSTRACT

The disclosure provides a three-dimensional (3D) memory, a method of fabricating a 3D memory and a memory system. The 3D memory can include a stack including alternately stacked first dielectric layers and conductive layers, and a channel structure extending through the stack and including a second dielectric layer and a blocking layer disposed in this order from outside to inside. The second dielectric layer can have a dielectric constant greater than or equal to 3.9.

### INCORPORATION BY REFERENCE

This present application claims the benefit of Chinese Patent Application No. 202211409948.3, filed on Nov. 11, 2022, which is incorporated herein by reference in its entirety.

### BACKGROUND

### Technical Field

The present disclosure is related to the field of semiconductor technologies. Specifically, the present disclosure is related to a three-dimensional (3D) memory, a fabricating method thereof and a memory system.

### Description of the Related Art

Memory devices with planar structures have practically reached their limit in scalability. In order to further increase memory capacity and reduce memory cost per bit, three-dimensional (3D) memories have been proposed. A 3D memory typically includes a stack of alternately stacked dielectric layers and gate layers. A 3D memory further includes channel structures extending through the stack.

It is to be appreciated that this part is provided partially for the purpose of providing a background to facilitate understanding the technologies. However, the description in this part is not necessarily known or understood by those skilled in the art before the filing date of the application.

### SUMMARY

The present disclosure provides a three-dimensional (3D) memory, a method of fabricating a 3D memory and a memory system. In an aspect of the present disclosure, a three-dimensional (3D) memory can include a stack having alternately stacked first dielectric layers and conductive layers, and a channel structure extending through the stack that includes a second dielectric layer and a blocking layer disposed in this order from outside to inside. The second dielectric layer can have a dielectric constant greater than or equal to 3.9. In a further implementation of the present disclosure, the dielectric constant of the second dielectric layer can be greater than or equal to 10.

In an implementation of the present disclosure, the blocking layer can include first blocking portions located on a surface of the second dielectric layer away from the first dielectric layers, and second blocking portions located at least on a surface of the second dielectric layer away from the conductive layers. The first blocking portions can have a thickness larger than that of the second blocking portions in the direction parallel with the first dielectric layers.

In an implementation of the disclosure, a surface of the blocking layer away from the second dielectric layer is even. Additionally, the surfaces of the first blocking portions away from the second dielectric layer can be flush with surfaces of the second blocking portions away from the second dielectric layer.

In an implementation of the disclosure, the first blocking portions have a thickness larger than that of the second dielectric layer in the direction parallel with the first dielectric layers.

In an implementation of the disclosure, the channel structure further include a storage layer, a tunneling layer and a channel layer disposed in this order from outside to inside with the storage layer being located on a surface of the blocking layer away from the second dielectric layer.

In accordance with another aspect of the disclosure, a memory system can include the 3D memory of any one of the implementations, as well as a memory controller coupled to the 3D memory and configured to control the 3D memory. The memory system can include a solid state drive or a memory card.

In accordance with yet another aspect of the disclosure, a method of fabricating a three-dimensional (3D) memory can include forming a channel hole in a stack including alternately stacked first dielectric layers and material layers, and forming a second dielectric layer and a blocking layer sequentially over an inner wall of the channel hole. The second dielectric layer can have a dielectric constant greater than or equal to 3.9.

In an implementation of the disclosure, the forming the channel hole in the stack includes forming a first channel hole extending through the stack, and removing a portion of the first dielectric layers to along the first channel hole form the channel hole.

In an implementation of the disclosure, the forming the blocking layer can further include forming a first blocking layer over a surface of the second dielectric layer, and removing a portion of the first blocking layer away from the material layers to form the blocking layer. The surface of the blocking layer away from the second dielectric layer can be even.

In an implementation of the disclosure, the forming the blocking layer can include forming a first blocking layer over a surface of the second dielectric layer, removing a portion of the first blocking layer away from the material layers to expose a surface of the second dielectric layer away from the material layers, and forming a second blocking layer over remaining portions of the first blocking layer and the exposed surface of the second dielectric layer. A surface of the second blocking layer away from the second dielectric layer can be even, and remaining portions of the first blocking layer and the second blocking layer form the blocking layer together.

In an implementation of the disclosure, the material layers include first sacrificial layers, and the method can further include removing the first sacrificial layers after forming the blocking layer, and forming conductive layers in spaces formed by removing the first sacrificial layers.

In an implementation of the disclosure, the material layers can include conductive layers, and the forming the stack can further include forming a second channel hole in a stack structure including the first dielectric layers and first sacrificial layers alternately stacked, removing the first sacrificial layers, and forming the conductive layers in spaces formed by removing the first sacrificial layers.

In an implementation of the disclosure, the forming the stack further includes filling a second sacrificial layer into the second channel hole before removing the first sacrificial layers, and removing the second sacrificial layer after forming the conductive layers.

In an implementation of the disclosure, the forming the channel hole in the stack can include removing a portion of the first dielectric layers through the second channel hole to form the channel hole.

In an implementation of the disclosure, the method further can further include forming a storage layer, a tunneling layer and a channel layer sequentially over the surface of the blocking layer, and forming a dielectric core in a space defined by the channel layer.

### BRIEF DESCRIPTION OF THE DRAWINGS

Other features, objects and advantages of the present disclosure will become more apparent from the detailed description of non-limiting implementations with reference to the following figures, in which:

FIG. 1 is a diagram of a 3D memory including peripheral circuits and a memory array in accordance with exemplary implementations of the disclosure.

FIG. 2 is an example equivalent circuit diagram of a memory block in accordance with exemplary implementations of the disclosure;

FIG. 3 is a block diagram of an example memory system including 3D memories in accordance with exemplary implementations of the disclosure;

FIG. 4 is a diagram of an example memory card including 3D memories in accordance with exemplary implementations of the disclosure;

FIG. 5 is a diagram of an example solid state drive (SSD) including 3D memories in accordance with exemplary implementations of the disclosure;

FIG. 6 is a structural diagram of a 3D memory in accordance with exemplary implementations of the disclosure;

FIG. 7 is a partially enlarged view of the portion within the dashed-line box in FIG. 6;

FIG. 8 is a flow chart of a method of fabricating a 3D memory in accordance with exemplary implementations of the disclosure; and

FIGS. 9 to 27 are diagrams of a semiconductor structure formed after some steps of a method of fabricating a 3D memory in accordance with exemplary implementations of the disclosure.

### DETAILED DESCRIPTION OF THE PREFERRED IMPLEMENTATIONS

Various aspects of the disclosure will be described in more details with reference to accompanying drawings to fully understand the technologies in the disclosure. It is to be appreciated that the detailed description is only for the purpose of explaining example implementations of the disclosure and in no way limit the scope of the disclosure. Throughout the specification, identical reference numerals refer to identical elements.

It is noted that references in this specification to “one implementation”, “an example implementation”, “some implementations”, “optionally”, “as an option” and the like indicate that a particular feature, structure, or characteristic may be included in the mentioned implementation(s), but not necessarily included in each implementation. Moreover, such phrases may not necessarily refer to the same implementation. Moreover, when a particular feature, structure, or characteristic is described in connection with an implementation, it would be within the knowledge of those skilled in the art to effect such feature, structure, or characteristic in connection with other implementations, whether or not specifically stated.

Generally, terminology may be understood at least in part from usage in the context. For example, the term “one or more” as used herein, depending at least in part upon the context, may be used to describe any feature, structure, or characteristic in a singular sense or may be used to describe combinations of features, structures or characteristics in a plural sense. Similarly, terms, such as “a,” “an,” or “the,” may be understood to convey a singular usage or to convey a plural usage, depending at least in part upon the context. In addition, the term “based on” may be understood as being not necessarily intended to convey an exclusive set of factors and may, instead, allow for existence of additional factors, which are not necessarily expressly described, depending at least in part on the context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but may also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A layer may extend over the entirety of an underlying or overlying structure or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layers thereupon, thereabove, and/or therebelow. A layer may include multiple layers.

In the figures, thicknesses, dimensions and shapes of components have been somewhat adjusted for easy illustration. The figures are only examples and not strictly drawn to scale. For example, as used herein, terms “approximate”, “about” and the like indicate approximation instead of degrees and are intended to mean inherent variations in measured or calculated values as realized a person having ordinary skill in the art in the art.

It is also to be appreciated that, as used herein, terms “include/includes/including”, “comprise/comprises/comprising”, “have/has/having” and/or “contain/contains/containing” indicate existence of the stated feature, element and/or component, but will not exclude existence or addition of one or more other features, elements, components and/or any combinations thereof. Furthermore, when the expression “at least one of” precedes a list of features, it indicates all the listed features instead of any individual element.

All the terms (including engineering terms and scientific and technical terms) used herein have the same meanings as those commonly understood by a person having ordinary skill in the art, unless otherwise specified. It is also to be appreciated that the terms defined in common dictionaries should be interpreted to have the meanings consistent with their context in the art and should not be interpreted ideally or formally, unless otherwise specified explicitly herein.

It is to be noted that implementations of the disclosure and features thereof may be combined where there are no conflicts. Furthermore, specific steps included in a method described herein may not necessarily be performed in the described order and instead may be performed in any other order or in parallel, unless otherwise specified explicitly herein or there is any conflict with the context. The disclosure will be described in details hereafter in connection with implementations with reference to accompanying drawings.

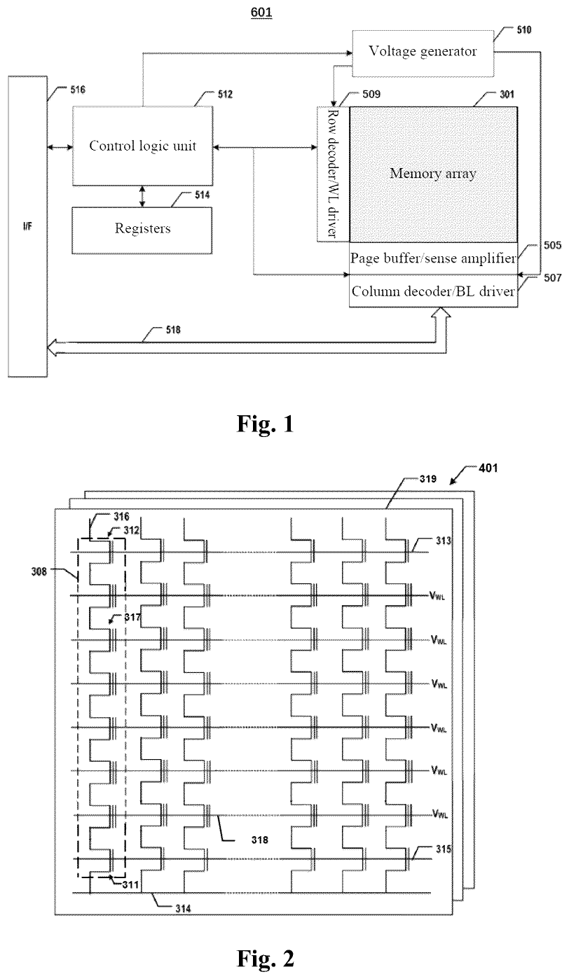

A three-dimensional (3D) memory architecture is typically formed by bonding a memory array and peripheral circuits together. FIG. 1 shows a diagram of a 3D memory 601 in accordance with exemplary implementations of the disclosure. The 3D memory 601 may be, for example, a 3D NAND memory or a 3D NOR memory. It is to be appreciated that the 3D memory 601 may be any example of the 3D memory 400 described below. In some implementations, the memory array 301 and peripheral circuits may be arranged on the same wafer. In other implementations, the memory array 301 and peripheral circuits may be arranged on different wafers, which may be electrically coupled with each other by processes such as bonding or the like. In some implementations, the 3D memory 601 is an integrated circuit (IC) package with one or more array chips and CMOS chips packaged therein.

With continued reference to FIG. 1, the memory array 301 may be a flash array, for example. The peripheral circuits may include, for example, a page buffer/sense amplifier 505, a column decoder/bit line driver 507, a row decoder/word line driver 509, a voltage generator 510, a control logic unit 512, registers 514, and I/F interface 516 and a data bus 518. It is to be appreciated that, in some examples, the peripheral circuits may include additional peripheral circuits not shown in FIG. 1.

In some examples, the page buffer/sense amplifier 505 may be configured to read/program (write) data from/to the memory array according to control signals from control logic unit 512. Optionally, the page buffer/sense amplifier 505 may buffer one page of programming data (writing data) to be programmed into one memory page of the memory array. In another example, during a read operation, the page buffer/sense amplifier 505 may sense a low-power signal at a bit line indicating the data bits stored in memory cells and amplify the small voltage swing to an identifiable logic level. The column decoder/bit line driver 507 may be configured to be controlled by the control logic unit 512 and select one or more memory cell strings 308, as shown in FIG. 2, by applying a bit line voltage generated by the voltage generator 510.

In some implementations, the row decoder/word line (WL) driver 509 may be configured to be controlled by the control logic unit 512, and select/deselect a memory block of the memory array and select/deselect a word line of the selected block. The row decoder/word line driver 509 may be further configured to drive word lines using word line voltages generated by the voltage generator 510. In some implementations, the row decoder/word line (WL) driver 509 may also select/deselect and drive source select lines (SSLs) and drain select lines (DSLs).

In some implementations, the voltage generator 510 may be configured to be controlled by the control logic unit 512, and generate various operation voltages (erase voltages, program voltages and read voltages) to be supplied to the memory array. For example, during a read operation, read voltages are supplied to the row decoder 509 to drive word lines (WLs) to read the memory cells 306 coupled thereto.

In some implementations, the control logic unit 512 may be coupled to each of peripheral circuits described above, and configured to control operations thereof. The control logic unit 512 may perform the method of operating the flash memory described below. The registers 514 may be coupled to the control logic unit 512 and include status registers, command registers and address registers to store status information, command operation codes (OP codes) and command addresses for controlling operations of each of the peripheral circuits.

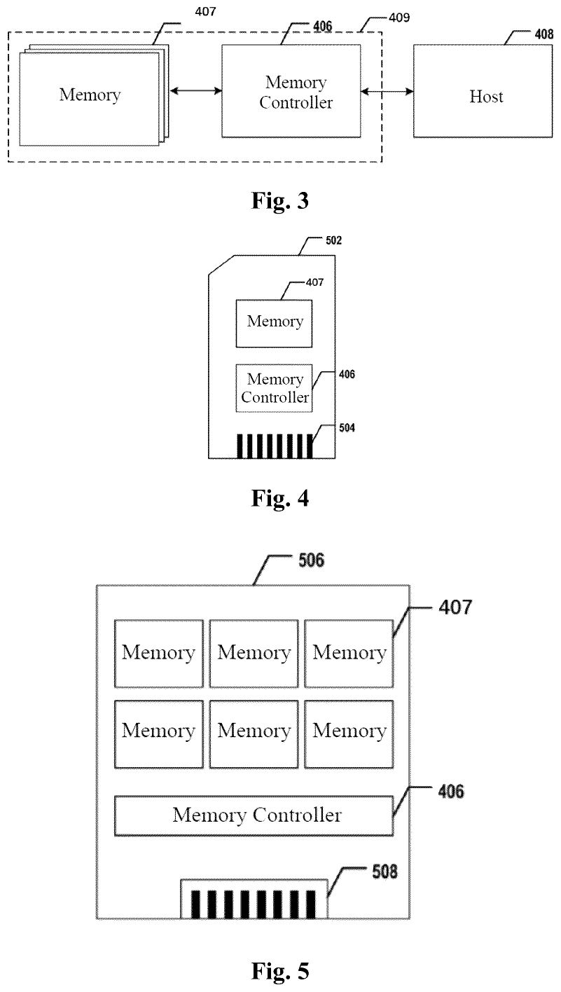

In some implementations, the I/F interface 516 may be coupled to the control logic unit 512, and serve as a control buffer so as to buffer and forward control commands received from a host (e.g., the host 408 shown in FIG. 3) to the control logic unit 512, and buffer and forward status information received from the control logic unit 512 to the host 408. The I/F interface 516 may also coupled to the column decoder/bit line driver 507 via the data bus 518 and serve as a data Input/output (I/O) interface and a data buffer so as to buffer and forward data to and from the memory array.

As shown in FIG. 2, the memory array 401 may include a plurality of memory blocks 319. In an example where the 3D memory 601 may be, for example, a 3D NAND memory, each memory block 319 may include a plurality of memory cell strings 308, each of which includes a plurality of memory cells 317 coupled in series and stacked vertically. Each memory cell 317 may hold continuous analog values, for example, voltages or charges, depending on the number of electrons trapped in the region of the memory cell 317. Each memory cell 317 may be a memory cell of a floating-gate type that includes a floating-gate transistor, or a memory cell of a charge-trapping type that includes a charge-trapping transistor.

In some implementations, the 3D memory 601 is of at least one of the SLC, MLC, TLC and QLC types. The SLC type means that each memory cell 317 stores 1 bit of data and has only two data states: “0” and “1”. The MLC type means that each memory cell stores 2 bits of data and has four data states: “00”, “01”, “10” and “11”. The TLC type means that each memory cell stores 3 bits of data and has eight data states: “000”, “001”, “010”, “011”, “100”, “101”, “110” and “111”. Similarly, the QLC type means that each memory cell 317 stores 4 bits of data and has sixteen data states. It can be appreciated that each memory cell 317 may store more than 4 bits of data.

With continued reference to FIG. 2, each memory cell string 308 may further include, at its drain end, a drain select gate transistor 312, which may also be referred to as a “top select gate transistor (i.e., TSG transistor)” in examples where the drain select gate transistor is disposed at the top of the memory cell string 308. Each memory cell string 308 may also include, at its source end, a source select gate transistor 311, which may also be referred to as a “bottom select gate (BSG) transistor” in examples where the source select gate transistor is disposed at the bottom of the memory cell string 308. The TSG transistor 312 and the BSG transistor 311 may be controlled by their respective top select gate TSG and bottom select gate BSG, and configured to activate the corresponding memory cell string 308 during operations of the 3D memory 601. In exemplary implementations, sources of the memory cell strings 308 in a same memory block 319 may be coupled together through a same source line 314. According to some implementations, each memory cell string 308 has its drain coupled to a corresponding bit line 316. In some implementations, corresponding select voltages may be applied to the gates of corresponding drain select gate transistors 312 via one or more drain select lines 313. In some implementations, corresponding select voltages may also be applied to the gates of corresponding source select gate transistors 311 via one or more source select lines 315.

Exemplary implementations of the disclosure provide a memory system 500 including a 3D memory, which may be any example of the 3D memory 601 described above. As shown in FIG. 3, the memory system 500 may be a mobile phone, a desktop computer, a laptop computer, a tablet, an in-vehicle computer, a gaming console, a printer, a positioning device, a wearable electronic device, a smart sensor, a virtual reality (VR) device, an argument reality (AR) device, or any other suitable electronic devices having memories therein. With continued respect to FIG. 3, the memory system 500 may include a host 408 and a memory system 409 having one or more memories 407 and a memory controller 406. The host 408 may be a processor of an electronic device, such as a central processing unit (CPU), or a system-on-chip (SoC), such as an application processor (AP). The host 408 may be configured to send or receive data stored in the memory 407.

According to some implementations, the memory controller 406 is coupled to the memory 407 and the host 408 and is configured to control the memory 407. The memory controller 406 may manage the data stored in the memory 407 and communicate with the host 408. In some implementations, the memory controller 406 is designed for operating in a low duty-cycle scheme, such as secure digital (SD) cards, compact Flash (CF) cards, universal serial bus (USB) Flash drives, or other media for use in electronic devices such as personal computers, digital cameras, mobile phones, etc. In some implementations, the memory controller 406 is designed for operating in a high duty-cycle SSDs or embedded multimedia cards (eMMCs) used as data storage for mobile devices (such as smartphones, tablets, laptop computers, etc.), and enterprise storage arrays. The memory controller 406 may be configured to control operations of the memory 407, such as read, erase, and program operations. The memory controller 406 may be further configured to manage various functions with respect to the data stored or to be stored in the memory 407, including but not limited to bad-block management, garbage collection, logical-to-physical address conversion, wear leveling, etc. In some implementations, the memory controller 406 is further configured to process error correction codes (ECCs) with respect to the data read from or written to the memory 407. Any other suitable functions may be performed by the memory controller 406, for example, formatting the memory 407. The memory controller 406 may communicate with an external device (e.g., the host 408) according to a particular communication protocol. For example, the memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

In some cases, the memory controller 406 and one or more memories 407 may be integrated into various types of storage devices, for example, included in the same package, such as a universal Flash storage (UFS) package or an eMMC package. That is, the memory system 409 may be implemented and packaged into different types of terminal electronic products. In one example as shown in FIG. 4, the memory controller 406 and a single memory 407 may be integrated into a memory card 502. The memory card 502 may include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. The memory card 502 may further include a memory card connector 504 coupling the memory card 502 with a host (e.g., the host 408 in FIG. 3). In another example as shown in FIG. 5, the memory controller 406 and multiple memories 407 may be integrated into an SSD 506. The SSD 506 may further include an SSD connector 28 coupling the SSD 506 with a host (e.g., the host 408 in FIG. 3). In some implementations, the storage capacity and/or the operation speed of the SSD 506 is greater than those of the memory card 502.

In order to increase the storage capacity of a 3D memory, the number of stacked tiers (the number of dielectric layer/gate layer pairs) in its stack is constantly increased. In order to limit the dimension of the 3D memory in the direction of the thickness of the stack, the widths of the gate layers and dielectric layers in the direction of the thickness of the stack are made relatively smaller, so that coupling (e.g., parasitic capacitive coupling) between every two adjacent memory cells (e.g., formed at the intersections of two adjacent gate layers and the channel structure) is correspondingly increased. For example, during a program operation of the 3D memory, charges in the gate layers are inevitably injected into the regions between adjacent memory cells (also referred to as “inter-cell regions” hereafter), so that the phenomenon of parasitic coupling between adjacent memory cells, also referred to as “inter-cell interference (ICI)”, influences the threshold voltages of the adjacent memory cells, and thus degrades their performance of operations (such as reading, writing and/or data holding).

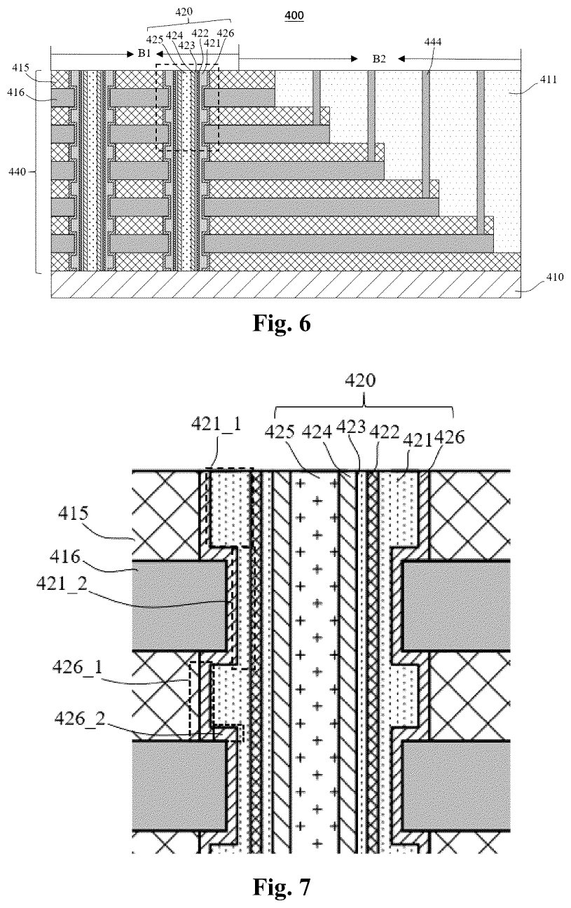

In order to solve the above-mentioned or other problems, some implementations of the disclosure provide a three-dimensional (3D) memory 400. For example, the 3D memory 400 may be any example of the 3D memory 601 described above. As shown in FIG. 6, the 3D memory 400 may include a semiconductor layer 410. Optionally, the materials used for the semiconductor layer 410 include, for example, silicon (e.g., monocrystal silicon, polysilicon), metals or metal nitrides. In some cases, the semiconductor layer 410 may also be doped, for example, with N-type conductive particles to improve its conductivity.

In some examples, the 3D memory 400 may further include a stack 440 over the semiconductor layer 410. Optionally, the stack 440 may include a plurality of alternately stacked first dielectric layers 415 and conductive layers 416. Optionally, conductive layers 416 may serve as gates for word line fan-out. In some examples, the materials used for the conductive layers 416 may include, for example, metal conductive materials such as W, Co, Cu, Al, Ti, Ta, Ni or the like. In some examples, the materials used for the first dielectric layers 415 may include, for example, semiconductor materials such as polysilicon, doped silicon, metal silicides (such as NiSix, WSix, CoSix, TiSix) or any combination thereof.

With continued reference to FIG. 6, in some examples, the stack 440 may include a core area B1 and a staircase area B2 adjacent with the core area B1. Optionally, the staircase area B2 may include a staircase structure that includes staircase steps each having at least one first dielectric layer 415/conductive layer 416 pair. As an option, the staircase area B2 may be located at the center of the core area B1; and as another option, the staircase area B2 may be located on both sides of the core area B1. The 3D memory 400 in accordance with implementations of the disclosure is not limited in the position relationship between the core area B1 and the staircase area B2.

In some examples, the 3D memory 400 may further include an insulating layer 411 over the staircase structure. Optionally, the surface of the insulating layer 411 away from the semiconductor layer 410 may be a substantially flattened surface. The materials used for the insulating layer 411 include, for example, silicon oxide. In some cases, the insulating layer 411 may, for example, provide structural support for contact structures 444 to be formed subsequently.

In some examples, the core area B1 of the 3D memory 400 includes a plurality of channel structures 420 extending through the stack 440. With the conductive layers 416 serving as gates, memory cells 317 described above may be formed at intersections of the channel structures 420 and the conductive layers 416. As one example, a channel structure 420 may include a second dielectric layer 426, a functional layer, a channel layer 424 and a dielectric core 425 disposed in this order from outside to inside.

In some examples, the second dielectric layer 426 may include dielectric materials (e.g., dielectric metal oxides). For example, the second dielectric layer 426 may include any dielectric metal oxide having an enough dielectric constant (e.g., greater than or equal to 3.9). Illustratively, the dielectric constant of the second dielectric layer 426 may further be, for example, greater than or equal to 10. The material used for the second dielectric layer 426 includes, for example, one of AlO, hafnium oxide (HfO₂), lanthanum oxide (LaO₂), yttrium oxide (Y₂O₃), tantalum oxide (Ta₂O₅), silicates thereof, nitrogen-doped compounds thereof and/or alloys thereof.

With reference to FIG. 7, the second dielectric layer 426 includes, for example, multiple first dielectric portions 426_1 extending in the direction of the thickness of the stack 440 and multiple second dielectric portions 426_2 extending in the direction parallel with the first dielectric layers 415. As one example, the thickness of the first dielectric portions 426_1 in the direction parallel with the first dielectric layers 415 may be substantially the same as the thickness of the second dielectric portions 426_2 in the extending direction of the channel structure 420. In some cases, the first dielectric portions 426_1 and the second dielectric portions 426_2 may be in contact with each other. In some other cases, the first dielectric portions 426_1 and the second dielectric portions 426_2 may form a continuous second dielectric layer 426. As one example, a first dielectric portion 426_1 corresponding to a first dielectric layer 415, together with its two adjacent second dielectric portions 426_2, may form a recess in the direction parallel with the first dielectric layers 415. As another example, a first dielectric portions 426_1 corresponding to a conductive layer 416, together with its two adjacent second dielectric portions 426_2, may form a protrusion in the direction parallel with the first dielectric layers 415. As an option, an end of a conductive layer 416 in the direction parallel with the first dielectric layers 415 may be covered by a corresponding first dielectric portion 426_1 and its two adjacent second dielectric portions 426_2.

In the 3D memory 400 in accordance with some implementations of the disclosure, since the end of the conductive layer 416 in the direction parallel with the first dielectric layers 415 may be covered by a corresponding first dielectric portion 426_1 and its two adjacent second dielectric portions 426_2, when bias voltages are applied to the conductive layers 416, voltage drops between every two adjacent conductive layers 416 may be alleviated, so that the risk of breakdown due to the discharging by the tips (e.g., ends) of the conductive layers 416 is reduced, improving the reliability of the device.

Optionally, the functional layer includes, for example, a blocking layer 421, a storage layer 422 and a tunneling layer 423 disposed in this order in the direction toward the channel layer 424. The blocking layer 421 is, for example, used to block the charges in the conductive layers 416 from being transported into the storage layer 422 to be described below. The materials used for the blocking layer 421 include, for example, insulating materials such as silicon oxide.

In an option, the surface of the blocking layer 421 away from the second dielectric layer 426 is even. When the surface of the blocking layer 421 away from the second dielectric layer 426 has a profile of cylinder or taper, the even surface of the blocking layer 421 away from the second dielectric layer 426 may be considered as the above-mentioned cylinder or taper shaped surface being a smooth surface, which shall be regarded as being smooth with errors within a tolerant range instead of being absolutely smooth (for example, as a surface without any obvious depression).

With continued reference to FIG. 7, as one example, the blocking layer 421 includes, for example, first blocking portions 421_1. The first blocking portions 421_1 may be, for example, surrounded by the first dielectric portions 426_1 along the circumference of the channel structure 420. As an option, the first blocking portions 421_1 may be on and in contact with the surface of second dielectric layer 426 away from the first dielectric layers 415. For example, the first blocking portions 421_1 may partially occupy the surfaces of the first dielectric portions 426_1 away from the first dielectric layers 415. Optionally, the first blocking portions 421_1 may also located in the recesses each formed by a first dielectric portion 426_1 and its two adjacent second dielectric portions 426_2.

As one example, the blocking layer 421 may further include second blocking portions 421_2. The second blocking portions 421_2 may be, for example, at least surrounded by the conductive layers 416 along the circumference of the channel structure 420. As an option, the second blocking portions 421_2 are at least on the surface of the second dielectric layer 426 away from the conductive layers 416. For example, a second blocking portion 421_2 may occupy the surface of a second dielectric portion 426_2 away from the conductive layers 416 and the surface, away from the conductive layers 416, of the first dielectric portion 426_1 between two adjacent second dielectric portions 426_2.

In some examples, the first blocking portions 421_1 have a thickness larger than that of the second blocking portions 421_2 in the direction parallel with the first dielectric layers 415.

With reference to FIG. 7, in the 3D memory 400 in accordance with some implementations of the disclosure, the first blocking portions 421_1 of the blocking layer 421 have a thickness larger than that of the second blocking portions 421_2 in the direction parallel with the first dielectric layers 415, so that the physical thickness in the direction of the thickness of the stack 440 and between the ends of the conductive layers 416 in contact with the channel structure 420 and, for example, the above-mentioned inter-cell regions may be increased.

Generally, the dielectric constant K, physical thickness THK and equivalent oxide thickness (EOT) of a film has a relationship: K=3.9×THK/EOT, where EOT is in direct proportion to THK when K remains constant. Therefore, increasing the above-mentioned THK may increase EOT correspondingly.

In examples where the conductive layers 416 serve as gates, for example, during application of bias voltages to the gates, the density of the electric field between the ends of the conductive layers 416 in contact with the channel structure 420 and the inter-cell regions is reduced due to the increased EOT discussed above, so that the leakage of charges into the inter-cell regions from the conductive layers 416 is reduced, reducing coupling (e.g., parasitic capacitive coupling) between adjacent memory cells and improving the performance of operations (such as reading, writing and/or data holding) of the memory cells.

Optionally, in some cases where the thickness of the first blocking portions 421_1 is larger than that of the second blocking portions 421_2, the surfaces of the first blocking portions 421_1 away from the second dielectric layer 426 are flush with the surfaces of the second blocking portions 421_2 away from the second dielectric layer 426 in the direction parallel with the first dielectric layers 415, so that the surface of the blocking layer 421 away from the second dielectric layer 426 remains even. The blocking layer 421 with the above-mentioned surface that remains even may further reduce the coupling (e.g., parasitic capacitive coupling) between adjacent memory cells.

As an option, the first blocking portions 421_1 may be in contact with the second blocking portions 421_2. As another option, the first blocking portions 421_1 and the second blocking portions 421_2 may form a continuous blocking layer 421.

Optionally, the thickness of the first blocking portions 421_1 is larger than that of the second dielectric layer 426 in the direction parallel with the first dielectric layers 415. Specifically, the thickness of the first blocking portions 421_1 may be larger than that of the second dielectric portions.

During operations of the 3D memory, the storage layer 422 may be used to, for example, trap charges from the channel layer 424 to be described below. The materials used for the storage layer 422 may include charge trapping materials including, for example, silicon nitride, silicon oxynitride, silicon or any combination thereof. In some examples, the storage layer 422 may be located on the surface of the blocking layer 421 away from the second dielectric layer 426. Optionally, the storage layer 422 may has a substantially uniform thickness in the direction parallel with the first dielectric layers 415.

In some examples, the tunneling layer 423 may include dielectric materials through which tunneling may occur under an appropriate bias. The materials used for the tunneling layer 423 may include silicon oxide, silicon oxynitride or any combination thereof. In one example, the functional layer may be a composite layer including silicon oxide/silicon oxynitride/silicon oxide (ONO). As one example, the tunneling layer 423 may be located on the surface of the storage layer 422 away from the blocking layer 421. Optionally, the tunneling layer 423 may has a substantially uniform thickness in any direction parallel with the first dielectric layers 415.

During operations of the 3D memory, the charges transported from the channel layer 424 may tunnel via the tunneling layer into the storage layer 422. The materials used for the channel layer 424 include, for example, polysilicon. In some cases, the channel layer 424 may be doped for conductivity (e.g., N-type or P-type doped for conductivity) to improve its conductivity. Optionally, the channel layer 424 may be, for example, in contact with the semiconductor layer 410.

With continued reference to FIG. 6, the channel structure 420 may further include the dielectric core 425 in the space defined by the channel layer 424. The materials used for the dielectric core 425 include, for example, silicon oxide.

In some examples, the 3D memory 400 further includes a semiconductor plug (not shown), that is located at the end of the channel structure 420 away from the semiconductor layer 410 and may be, for example, in contact with the channel layer 424. Optionally, the 3D memory 400 further includes a plurality of contact structures 444 in the staircase area B2. As an option, the contact structures 444 may go through the insulating layer 411 in the staircase area B2 and extend to their respective conductive layers 416 at corresponding staircase steps. With the conductive layers 416 serving as gates, the contact structures 444 may be used for word line fan-out.

In some examples, the 3D memory 400 may further include dummy channel structures (not shown) in the staircase area B2. The dummy channel structures may each extend through the insulating layer 411 into the semiconductor layer 410. In some cases, the dummy channel structures may provide structural support for the staircase structure. Optionally, the materials used for the dummy channel structures include, for example, insulating materials such as silicon oxide. Optionally, the internal structure of the dummy channel structures may be the same as that of the channel structures 420.

In some examples, the 3D memory 400 further includes gate line slit structures (not shown) each extending through the stack 440 into the semiconductor layer 410. Optionally, the gate line slit structures may each include an isolation layer (not shown) and a conductor layer (not shown) disposed in this order from outside to inside. Optionally, the isolation layer is used to isolate conductive layers of every two adjacent tiers from each other.

In some examples, the 3D memory 400 further includes peripheral circuits (not shown) including a substrate and peripheral circuit structures (not shown) over the substrate. Optionally, the peripheral circuit structures (not shown) may include, for example, high-voltage devices for controlling high-voltage signals and/or low-voltage devices for improving reading/writing speed. Optionally, the above-mentioned high-voltage devices and/or low-voltage devices may include, for example, MOS transistors (not shown). Optionally, the 3D memory 400 may further include an interconnect layer over the peripheral circuit structures.

In some cases, the peripheral circuits and the memory array 301 (FIG. 1) are bonded together in a face-to-face manner. That is, the peripheral circuits and the memory array 301 have their respective interconnect layers in corresponding contact with each other at the bonding interface and thereby are electrically connected. During operations of the 3D memory, the peripheral circuits may control the memory cell strings 308 in the memory array 301 (FIG. 2) by electrically connecting the memory array 301 and the peripheral circuits.

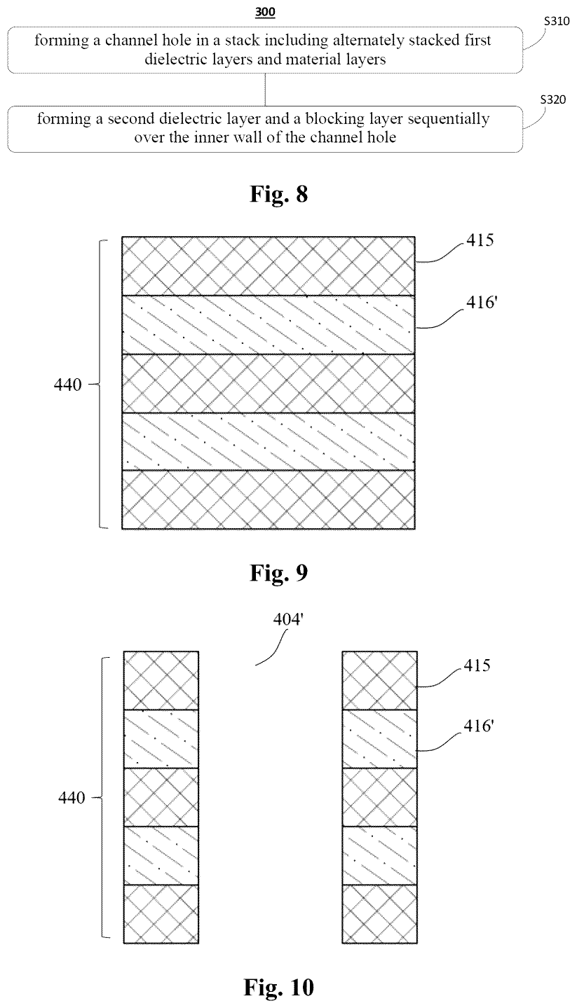

Exemplary implementations of the disclosure further provide a method 300 of fabricating a 3D memory, which involves some operations of forming the channel structures 420 of the 3D memory 400 described above. FIG. 8 is a flow chart of a method 300 of fabricating a 3D memory according to some implementations of the disclosure, and FIGS. 9-27 are partial diagrams of semiconductor structures formed after performing some steps of the method of fabricating a 3D memory in accordance with some implementations of the disclosure.

In detailed description of implementations of the disclosure, for easy illustration, cross-sections depicting device structures are partially exaggerated instead of being drawn to general scale. The diagrams are just illustrative and in no way limit the scope of the disclosure.

The fabricating method 300 will be described in details in connection with FIGS. 9-27 hereafter. It is to be appreciated that the operations shown in the method are not exhaustive and that other operations may be performed as well before, after, or between any of the illustrated operations.

With reference to FIG. 8, the method 300 includes operation S310, in which a channel hole is formed in a stack including alternately stacked first dielectric layers and material layers. As shown in FIG. 9, to form the stack 440, a plurality of first dielectric layers 415 and material layers (e.g., first sacrificial layers 416′) are alternately stacked over, for example, a substrate (not shown) by one or more thin film forming processes such as chemical vapor deposition (CVD), physical vapor deposition (PVD), atomic layer deposition (ALD), sputtering, thermal oxidation or any combination thereof. Optionally, the materials used for the substrate include silicon (such as single crystal silicon and polysilicon), silicon germanium (SiGe), germanium (Ge), silicon on insulator (SOI), germanium on insulator (GOI), gallium arsenide (GaAs), gallium nitride (GaN), silicon carbide (SiC) or any combinations thereof. Illustratively, as described hereafter, the substrate is used to provide mechanical support for the channel structures 420 and the like to be formed thereover and may be removed at least in part during a later process.

In some examples, the number of tiers in which the first dielectric layers 415 and first sacrificial layers 416′ are stacked in the stack 440 may be, for example, 8, 32, 64, 128 or more. The disclosure is not specifically limited in the number of tiers in which the first dielectric layers 415 and first sacrificial layers 416′ are stacked. In some cases, the materials used for the first dielectric layers 415 and first sacrificial layers 416′ satisfy that the first sacrificial layers 416′ may have a high etching selectivity with respect to the first dielectric layers 415 in a same etching process, so that the first dielectric layers 415 are barely removed in the later process of removing the first sacrificial layers 416′. In addition, any suitable materials known in the art may be selected for the first dielectric layers 415 and first sacrificial layers 416′. For example, the first dielectric layers 415 may be oxide layers (e.g., silicon oxide) and the first sacrificial layers 416′ may be nitride layers (e.g., silicon nitride).

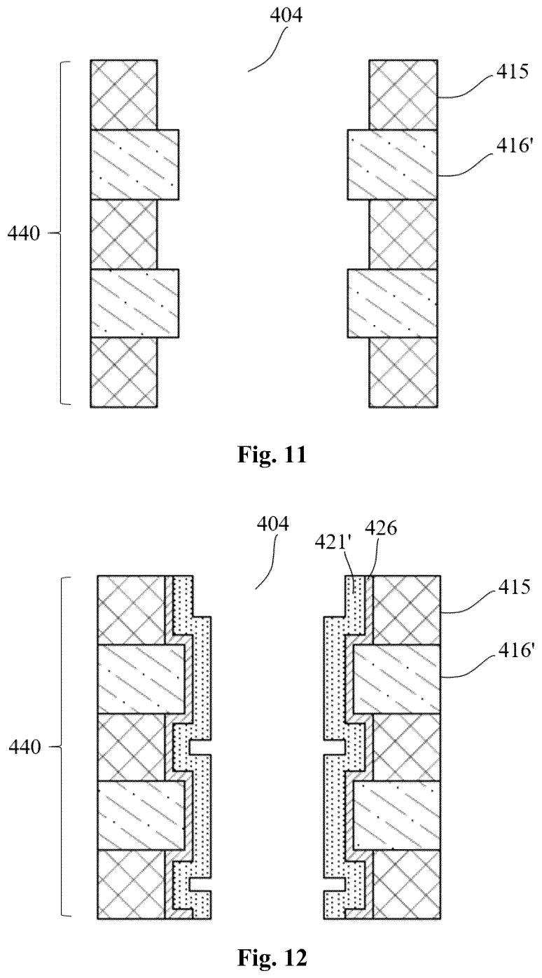

In some example processes after formation of the stack 440 as shown in FIG. 9, a channel hole 404 may be formed in the stack 440 (e.g., at the location corresponding to the core area B1 involved in the forgoing description of 3D memory 400), as shown in FIG. 11. Specifically, with reference to FIG. 10, a plurality of first channel holes 404′ are formed in the stack 440 by photolithography and etching processes. In some examples, a first channel hole 404′ has a profile of, for example, cylinder or taper. Illustratively, a portion of the first dielectric layers 415 along the first channel hole 404′ is removed by one of dry etching, wet etching or plasma etching to form the channel hole 404 as shown in FIG. 11.

As one example, during the process of, for example, removing a portion of the first dielectric layers 415 along the first channel hole 404′ using an etching process, the first dielectric layers 415 have a high etching selectivity with respect to the first sacrificial layers 416′, so that the risk of causing damage to the first sacrificial layers 416′ is reduced.

As one example, after the processing above, the surface of a first dielectric layer 415 along the channel hole 404, together with adjacent first sacrificial layers 416′ (e.g., two first sacrificial layers 416′ in the direction of thickness of the stack 440), may form a recess.

As one example, after the processing above, the surface of the first sacrificial layers 416′ exposed in the channel hole 404 forms protrusions. In some cases, the thickness of the removed portion of a first dielectric layer 415 (e.g., in the direction parallel with the first dielectric layers 415) may be any suitable offset allowed between the surfaces of its adjacent first sacrificial layers 416′ at the recess (e.g., the surfaces along the direction of thickness of the stack 440) and the first dielectric layer 415 (e.g. the surface along the direction of thickness of the stack 440).

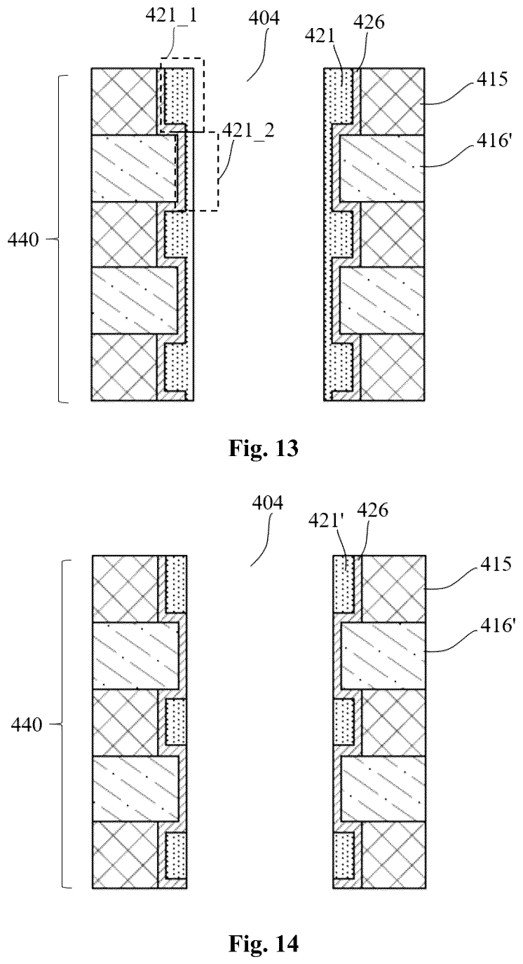

Returning to FIG. 8, the method 300 includes operation S320, in which a second dielectric layer and a blocking layer are formed sequentially over the inner wall of the channel hole. Referring to FIG. 13, in some examples, a second dielectric layer 426 may be formed over the inner wall of the channel hole 404 using one or more thin film deposition processes such as CVD, PVD, ALD or any combination thereof.

As an option, the second dielectric layer 426 may be formed over the surfaces of the recesses formed by removing a portion of the first dielectric layers 415 as described above and over the inner wall of the first channel hole 404′. After the processing above, the ends of the first sacrificial layers 416′ in the direction parallel with the first dielectric layers 415 may be covered by the second dielectric layer 426. Specifically, an end of a first sacrificial layer 416′ in the direction parallel with the first dielectric layers 415 may be covered by a first dielectric portion 426_1 (e.g., one corresponding to a conductive layer 416) and two adjacent second dielectric portions 426_2 as discussed above with respect to the 3D memory 400.

In some examples, the second dielectric layer 426 may include dielectric materials (e.g., dielectric metal oxides). For example, the second dielectric layer 426 may include a dielectric metal oxide having an enough dielectric constant (e.g., greater than or equal to 3.9). Illustratively, the dielectric constant of the second dielectric layer 426 may further be, for example, greater than or equal to 10. The material used for the second dielectric layer 426 includes, for example, one of AlO, hafnium oxide (HfO₂), lanthanum oxide (LaO₂), yttrium oxide (Y₂O₃), tantalum oxide (Ta₂O₅), silicates thereof, nitrogen-doped compounds thereof and/or alloys thereof.

With continued reference to FIG. 13, in some examples, a blocking layer 421 having a suitable thickness may be formed over the surface of the second dielectric layer 426. As one example, the portions of the second dielectric layer 426 surrounded by the first dielectric layers 415 may have a thickness in the direction parallel with the first dielectric layers 415, which is, for example, less than the above-mentioned offset, so that the blocking layer 421 may be formed to at least fully fill up the recesses. Optionally, the blocking layer 421 may include, for example, a material different from that of the second dielectric layer 426. Optionally, the material used for the blocking layer 421 is, for example, one of silicon oxide, silicon oxynitride and silicon nitride.

Referring to FIG. 12, in some example processes for forming the blocking layer 421, a first blocking layer 421′ may be formed over the surface of the second dielectric layer 426 through the channel hole 404 using one or more thin film deposition processes such as CVD, PVD, ALD or any combination thereof. As one example, the first blocking layer 421′ may at least fully fill up the recesses. Optionally, the portions of the first blocking layer 421′ at least surrounded by the first sacrificial layers 416′ form protrusions toward the channel hole 404.

With continued reference to FIG. 13, in some example processes using, for example, an ALD deposition process for forming the first blocking layer 421′, a thinning process may be performed on the thickness of the first blocking layer 421′ (e.g., the thickness in the direction parallel with the first dielectric layers 415) by removing a portion of the first blocking layer 421′ away from the material layers (e.g., the first sacrificial layers 416′) using, for example, one of dry etching, wet etching or plasma etching, until the blocking layer 421 is formed.

The surface of the blocking layer 421 away from the second dielectric layer 426, formed through the above-mentioned thinning process, is even. When the surface of the blocking layer 421 away from the second dielectric layer 426 has a profile of cylinder or taper, the even surface of the blocking layer 421 away from the second dielectric layer 426 may be considered as the above-mentioned cylinder or taper shaped surface being a smooth surface, which shall be regarded as being smooth with errors within a tolerant range instead of being absolutely smooth (for example, as a surface without any obvious depression).

With continued reference to FIG. 13, after the processing above, the portions (e.g., the first blocking portions 421_1) of the blocking layer 421 surrounded by the first dielectric layers 415 along the circumference of the channel hole 404 may have a thickness in the direction parallel with the first dielectric layers 415, which is larger than that of the portions (e.g. the second blocking portions 421_2) at least surrounded by the first sacrificial layers 416′ along the circumference of the channel hole 404. As an option, the first blocking portions 421_1 are, for example, located on the surface of the second dielectric layer 426 away from the first dielectric layers 415; and the second blocking portions 421_2 are at least located on the surface of the second dielectric layer 426 away from the first sacrificial layers 416′.

With reference to FIG. 14, in some example processes using, for example, a CVD process, a thinning process may be performed on the thickness of the first blocking layer 421′ (e.g., the thickness in the direction parallel with the first dielectric layers 415) by removing a portion of the first blocking layer 421′ away from the material layers (e.g., the first sacrificial layers 416′) using, for example, one of dry etching, wet etching or plasma etching, until the surface of the second dielectric layer 426 away from the material layers (e.g., the first sacrificial layers 416′) are exposed.

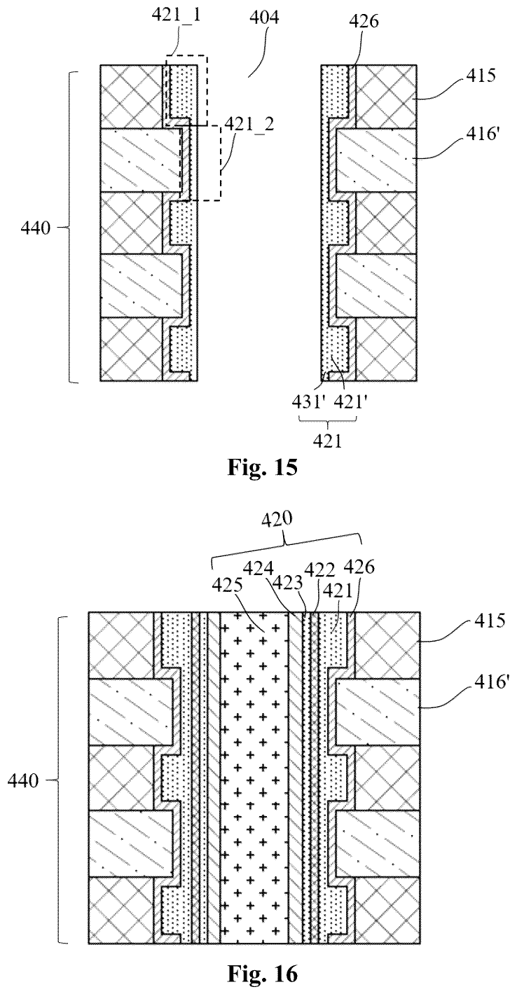

With reference to FIG. 15, in some example processes after the surface of the second dielectric layer 426 away from the material layers (e.g., the first sacrificial layers 416′) being exposed, a second blocking layer 431′ may be formed on the remaining portions of the first blocking layer 421′ and the exposed surface of the second dielectric layer 426 away from the material layers (e.g., the first sacrificial layers 416′). The processes for forming the second blocking layer 431′ include, for example, an ALD deposition process.

In some cases, the surface of the second blocking layer 431′ away from the second dielectric layer 426 is even. when the surface of the second blocking layer 431′ away from the second dielectric layer 426 has a profile of cylinder or taper, the even surface of the second blocking layer 431′ away from the second dielectric layer 426 may be considered as the above-mentioned cylinder or taper shaped surface being a smooth surface, which should be regarded as being smooth with errors within a tolerant range instead of being absolutely smooth (for example, as a surface without any obvious depression). As one example, the remaining portions of the first blocking layer 421′ and the second blocking layer 431′ form the blocking layer 421 together.

With continued reference to FIG. 15, after the processing above, the portions (e.g., the first blocking portions 421_1) of the blocking layer 421 surrounded by the first dielectric layers 415 along the circumference of the channel hole 404 may have a thickness in the direction parallel with the first dielectric layers 415, which is larger than that of the portions (e.g. the second blocking portions 421_2) at least surrounded by the first sacrificial layers 416′ along the circumference of the channel hole 404. As an option, the first blocking portions 421_1 are, for example, located on the surface of the second dielectric layer 426 away from the first dielectric layers 415; and the second blocking portions 421_2 are at least located on the surface of the second dielectric layer 426 away from the first sacrificial layers 416′.

With respect to the blocking layer 421 formed using the method 300 in accordance with some implementations of the disclosure, the thickness of the first blocking portions 421_1 in the direction parallel with the first dielectric layers 415 is larger than that of the second blocking portions 421_2 of the blocking layer 421, so that the equivalent oxide thickness (EOT) in the direction of the thickness of the stack 440 and between the ends of the conductive layers 416 in contact with the channel structure 420 and the inter-cell regions described above may be increased. In examples where the conductive layers 416 serve as gates, for example, during application of bias voltages to the gates, the density of the electric field between the ends of the conductive layers 416 in contact with the channel structure 420 and the inter-cell regions is reduced due to the increased EOT discussed above, so that the leakage of charges into the inter-cell regions from the conductive layers 416 is reduced, reducing coupling (e.g., parasitic capacitive coupling) between adjacent memory cells and improving the performance of operations (such as reading, writing and/or data holding) of the memory cells.

In accordance with the example processes for forming the blocking layer 421 as shown in FIGS. 14 and 15, the first blocking layer 421′ may be formed using a CVD process, which has low cost and relatively higher deposition speed, while the second blocking layer 431′ may be formed using an ALD deposition process. Using the processing above, the quality of the thin film deposition may be guaranteed while taking economic effects into account.

Referring to FIG. 16, in some example processes after forming the blocking layer 421, a storage layer 422 and a tunneling layer 423 may be sequentially formed over the surface of the blocking layer 421 using one or more thin film deposition processes such as CVD, PVD, ALD or any combination thereof. During operations of the 3D memory, the storage layer 422 may be used to, for example, trap charges from the channel layer 424 to be described below. The materials used for the storage layer 422 may include, for example, charge trapping materials, which may include, for example, silicon nitride, silicon oxynitride, silicon or any combination thereof. The tunneling layer 423 may include dielectric materials through which tunneling may occur under an appropriate bias. The materials used for the tunneling layer 423 may include silicon oxide, silicon oxynitride or any combination thereof.

With continued reference to FIG. 16, as one example, a channel layer 424 may be formed over the surface of the tunneling layer 423 using one or more thin film deposition processes such as CVD, PVD, ALD or any combination thereof. During operations of the 3D memory, the charges transported from the channel layer 424 may tunnel via the tunneling layer into the storage layer 422. The materials used for the channel layer 424 include, for example, polysilicon. In some cases, the channel layer 424 may be doped for conductivity (e.g., N-type or P-type doped for conductivity) to improve its conductivity.

With continued reference to FIG. 16, as one example, a dielectric core 425 may be formed in the space defined by the channel layer 424 using one or more thin film deposition processes such as CVD, PVD, ALD or any combination thereof, so as to form the channel structure 420. The materials used for the dielectric core 425 include, for example, silicon oxide.

In some example processes after forming the channel structure 420, a conductive plug (not shown) may be formed at the top of the channel structure 420 away from the substrate and in contact with the channel layer 424. In some examples, the conductive plug may serve as a part of the drain of the corresponding memory cell string 308 (FIG. 2). The materials used for the conductive plug include, for example, polysilicon.

In some other examples, after forming the channel structure 420, a staircase structure may be formed, for example, in the staircase area B2 involved in the description of the 3D memory 400, as shown in FIG. 6. Illustratively, an “etch-trim” process may be performed multiple times on the plurality of alternately stacked first dielectric layers 415 and first sacrificial layers 416′ to form the staircase structure. Optionally, each staircase step of the staircase structure includes at least one first dielectric layer/first sacrificial layer pair. Optionally, after forming the staircase structure, an insulating layer (e.g., the insulating layer 411 as shown in FIG. 6) may be formed to cover the staircase structure.

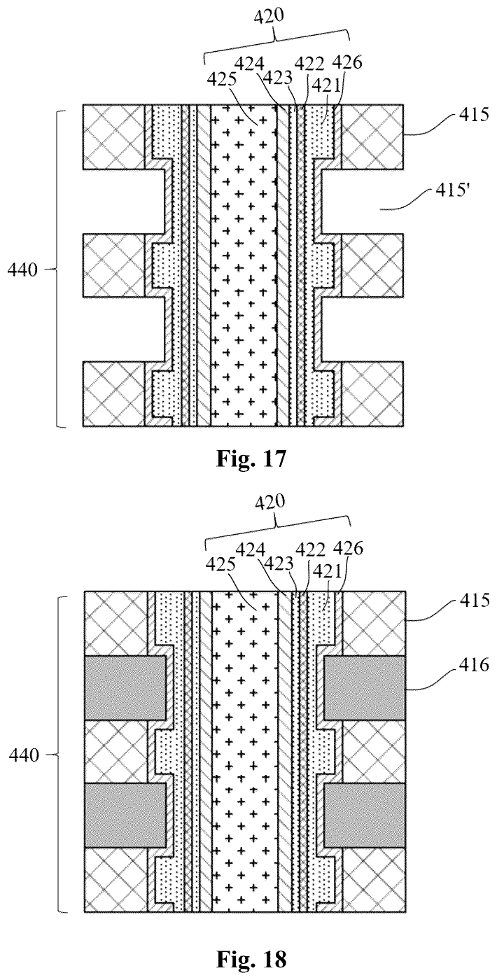

With reference to FIG. 18, in some example processes after forming the channel structure 420, the first sacrificial layers 416′ may be replaced with conductive layers 416. Specifically, the first sacrificial layers 416′ may be removed and conductive layers 416 may be formed in the spaces formed by removing the first sacrificial layers 416′. As an example of forming the conductive layers 416, a gate line slit (not shown) may be formed in the stack 440, and then the first sacrificial layers 416′ may be removed through the gate line slit, for example, using a wet etching process, so as to form the sacrificial spaces 415′ as shown in FIG. 17.

In some cases, the surface of the second dielectric layer 426 away from the blocking layer 421 may be exposed through the operation of forming the sacrificial spaces 415′ by removing the first sacrificial layers 416′. As an option, the conductive layers 416 may be formed by filling conductive materials into the sacrificial spaces 415′, as shown in FIG. 18. After the processing above, the ends of the conductive layers 416 in the direction parallel with the first dielectric layers 415 may be covered by the second dielectric layer 426. Specifically, an end of a conductive layer 416 in the direction parallel with the first dielectric layers 415 may be covered by a first dielectric portion and two adjacent second dielectric portions as discussed above with respect to the 3D memory 400.

Since the second dielectric layer 426 formed by the method 300 in accordance with some implementations of the disclosure may cover the ends of the conductive layers 416 in the direction parallel with the first dielectric layers 415, when bias voltages are applied to the conductive layers 416, voltage drops between every two adjacent conductive layers 416 may be alleviated, so that the risk of breakdown due to the discharging by the tips (e.g., ends) of the conductive layers 416 is reduced, improving the reliability of the device.

Optionally, the first sacrificial layers 416′ may have a high etching selectivity with respect to the first dielectric layers 415, so that the first dielectric layers 415 are barely removed during the process of removing the first sacrificial layers 416′. Optionally, the conductive layers 416 may serve as gates for word line fan-out. In some examples, the materials used for the conductive layers 416 may include, for example, metal conductive materials such as W, Co, Cu, Al, Ti, Ta, Ni or the like.

In some examples, after forming the conductive layers 416, insulating materials may be deposited over the inner wall of the gate line slit using one or more thin film deposition processes such as CVD, PVD, ALD or any combination thereof and then conductive materials may be filled into the gate line slit.

In some other example processes after forming the stack 440 (e.g., a stack structure), the gate line slit (not shown) may be formed and the first sacrificial layers 416′ may be replaced with the conductive layers 416 through the gate line slit, for example, before forming the channel structure 420.

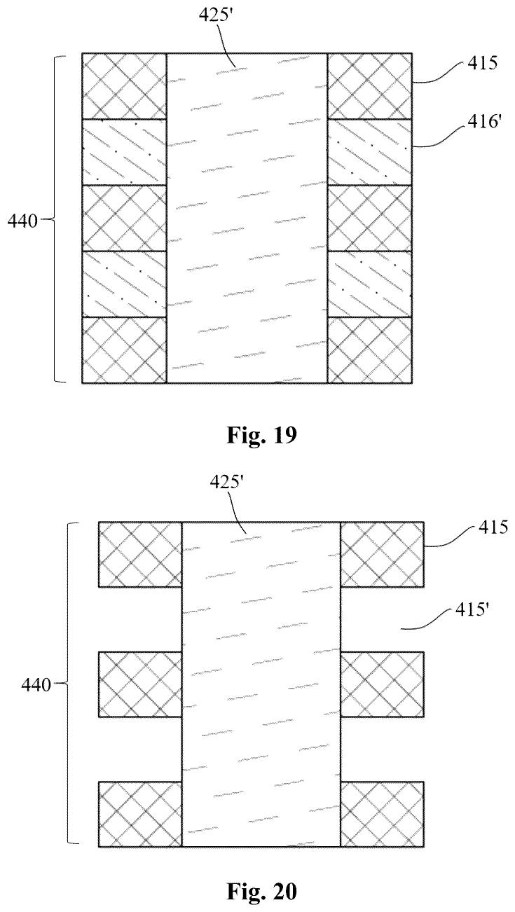

In some specific examples, a plurality of second channel holes (not shown) may be formed in the stack structure by photolithography and etching processes, for example, at locations corresponding to the core area B1 involved in the forgoing description of the 3D memory 400. In some examples, a second channel hole has a profile of, for example, cylinder or taper. Referring to FIG. 19, a second sacrificial layer 425′ may be filled into the second channel hole using one or more thin film deposition processes such as CVD, PVD, ALD or any combination thereof.

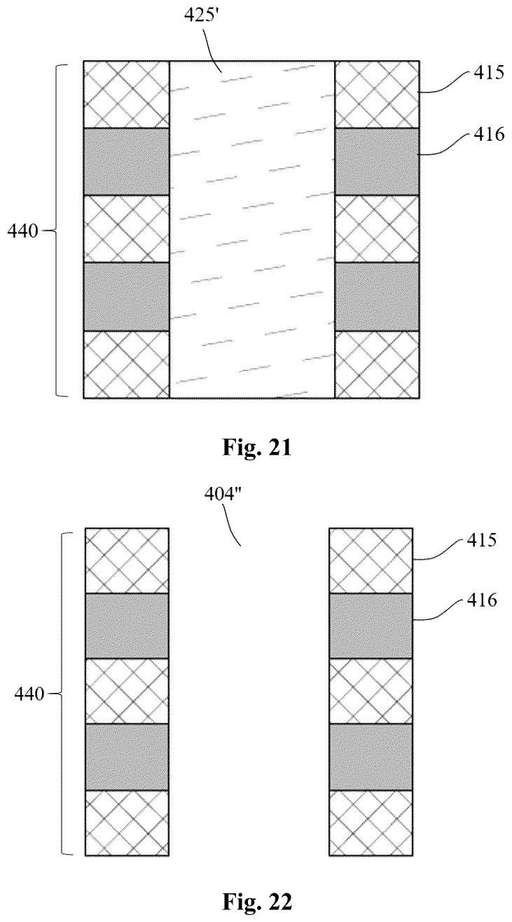

As another example of forming the conductive layers 416, after forming the second sacrificial layer 425′, a gate line slit (not shown) may be formed in the stack structure, and then the first sacrificial layers 416′ may be removed through the gate line slit, for example, using a wet etching process, so as to form the sacrificial spaces 415′ as shown in FIG. 20. In some cases, the materials used for the second sacrificial layer 425′ include, for example, polysilicon. As an option, the conductive layers 416 may be formed by filling conductive materials into the sacrificial spaces 415′, as shown in FIG. 21.

Reference to FIG. 22, in some example processes after forming the conductive layers 416, the second sacrificial layer 425′ may be removed, for example, using one of dry etching, wet etching or plasma etching. During the process of removing the second sacrificial layers 425′, for example, using an etching process, the second sacrificial layer 425′ may have a high etching selectivity with respect to the first dielectric layers 415 and the conductive layers 416, so that the risk of causing damage to the first dielectric layers 415 and the conductive layers 416 is reduced.

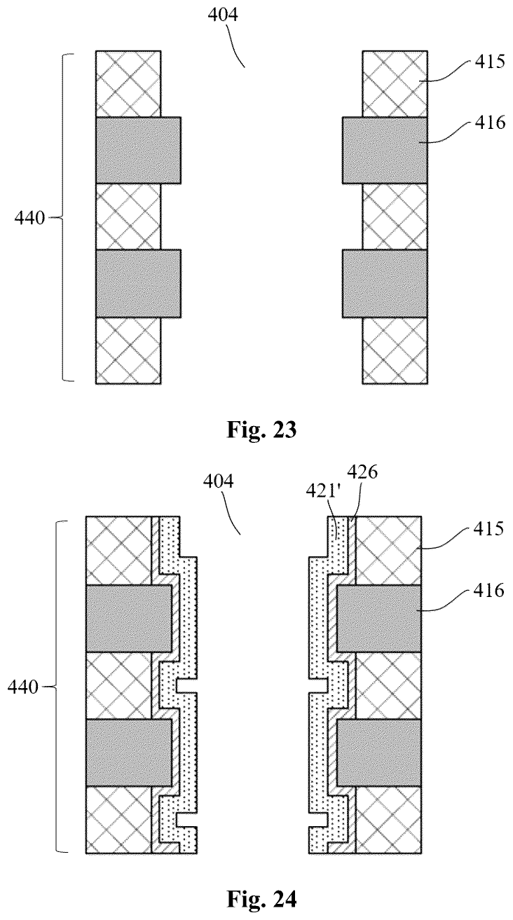

Reference to FIG. 23, a portion of the first dielectric layers 415 along the second channel hole may be removed using one of dry etching, wet etching or plasma etching, to form the channel hole 404 as described above. As one example, during the process of removing the portion of the first dielectric layers 415 along the second channel hole, for example, using an etching process, the first dielectric layers 415 have a high etching selectivity with respect to the conductive layers 416′, reducing the risk of causing damage to the first sacrificial layers 416′.

After the processing above, the surface of a first dielectric layer 415 along the channel hole 404, together with adjacent first sacrificial layers 416′ (e.g., two first sacrificial layers 416′ in the direction of thickness of the stack 440), may form a recess.

After the processing above, the surface of a first sacrificial layer 416′ exposed in the channel hole 404 may form a protrusion. In some cases, the thickness of the removed portion of a first dielectric layer 415 (e.g., in the direction parallel with the first dielectric layers 415) may be any suitable offset allowed between the surfaces of its adjacent first sacrificial layers 416′ at the recess (e.g., the surfaces along the direction of thickness of the stack 440) and the first dielectric layer 415 (e.g. the surface along the direction of thickness of the stack 440).

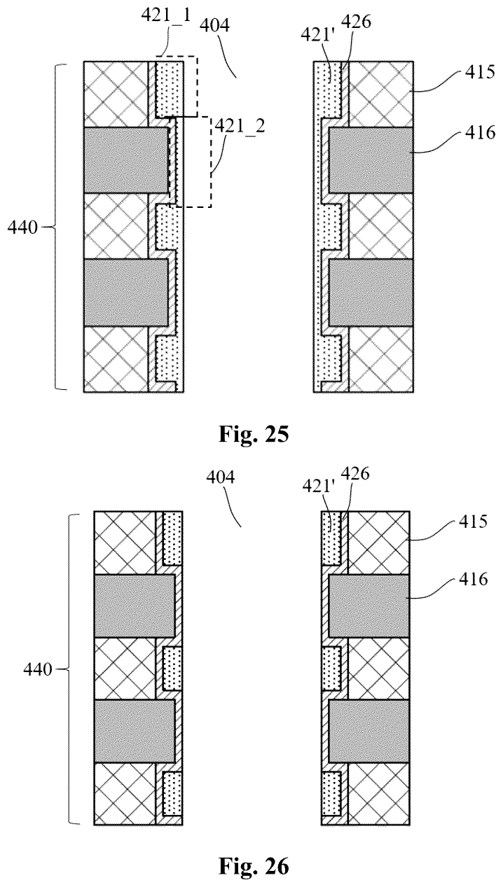

Referring to FIG. 25, in some example processes after forming the channel hole 404, a second dielectric layer 426 may be formed over the inner wall of the channel hole 404 using one or more thin film deposition processes such as CVD, PVD, ALD or any combination thereof.

Specifically, the second dielectric layer 426 may be formed over the surfaces of the recesses formed by removing a portion of the first dielectric layers 415 and over the inner wall of the first channel hole 404′. After the processing above, the ends of the first conductive layers 416 in the direction parallel with the first dielectric layers 415 may be covered by the second dielectric layer 426. Specifically, an end of a first conductive layers 416 in the direction parallel with the first dielectric layers 415 may be covered by a first dielectric portion and two adjacent second dielectric portions as discussed above with respect to the 3D memory 400.

Since the second dielectric layer 426 formed by the method 300 in accordance with some implementations of the disclosure may cover the ends of the conductive layers 416 in the direction parallel with the first dielectric layers 415, when bias voltages are applied to the conductive layers 416, voltage drops between every two adjacent conductive layers 416 may be alleviated, so that the risk of breakdown due to the discharging by the tips (e.g., ends) of the conductive layers 416 is reduced, improving the reliability of the device.

In some examples, the second dielectric layer 426 may include dielectric materials (e.g., dielectric metal oxides). For example, the second dielectric layer 426 may include a dielectric metal oxide having an enough dielectric constant (e.g., greater than or equal to 3.9). Illustratively, the dielectric constant of the second dielectric layer 426 may further be, for example, greater than or equal to 10. The material used for the second dielectric layer 426 includes, for example, one of AlO, hafnium oxide (HfO₂), lanthanum oxide (LaO₂), yttrium oxide (Y₂O₃), tantalum oxide (Ta₂O₅), silicates thereof, nitrogen-doped compounds thereof and/or alloys thereof.

With continued reference to FIG. 25, in some examples, a blocking layer 421 having a suitable thickness may be formed over the surface of the second dielectric layer 426. As one example, the portions of the second dielectric layer 426 surrounded by the first dielectric layers 415 may each have a thickness in the direction parallel with the first dielectric layers 415, which is, for example, less than the above-mentioned offset, so that the blocking layer 421 may be formed to at least fully fill up the recesses. Optionally, the blocking layer 421 may include, for example, a material different from that of the second dielectric layer 426. Optionally, the material used for the blocking layer 421 is, for example, one of silicon oxide, silicon oxynitride and silicon nitride.

Referring to FIG. 24, in some example processes for forming the blocking layer 421, a first blocking layer 421′ may be formed over the surface of the second dielectric layer 426 through the channel hole 404 using one or more thin film deposition processes such as CVD, PVD, ALD or any combination thereof. As one example, the first blocking layer 421′ may at least fully fill up the recesses. Optionally, the portions of the first blocking layer 421′ at least surrounded by the material layers (e.g., the conductive layers 416) further form protrusions toward the channel hole 404.

With continued reference to FIG. 25, in some example processes using, for example, an ALD deposition process for forming the first blocking layer 421′, a thinning process may be performed on the thickness of the first blocking layer 421′ (e.g., the thickness in the direction parallel with the first dielectric layers 415) by removing a part of the first blocking layer 421′ away from the material layers (e.g., the conductive layers 416) using, for example, one of dry etching, wet etching or plasma etching, until the blocking layer 421 is formed.

The surface of the blocking layer 421 away from the second dielectric layer 426 that is formed through the above-mentioned thinning process is even. When the surface of the blocking layer 421 away from the second dielectric layer 426 has a profile of cylinder or taper, the even surface of the blocking layer 421 away from the second dielectric layer 426 may be considered as the above-mentioned cylinder or taper shaped surface being a smooth surface, which should be regarded as being smooth with errors within a tolerant range instead of being absolutely smooth (for example, as a surface without any obvious depression).

With reference to FIG. 26, in some example processes using a CVD deposition process for forming the first blocking layer 421′, a thinning process may be performed on the thickness of the first blocking layer 421′ (e.g., the thickness in the direction parallel with the first dielectric layers 415) by removing a part of the first blocking layer 421′ away from the material layers (e.g., the conductive layers 416) using, for example, one of dry etching, wet etching or plasma etching, until the surface of the second dielectric layer 426 away from the material layers (e.g., the conductive layers 416) is exposed.

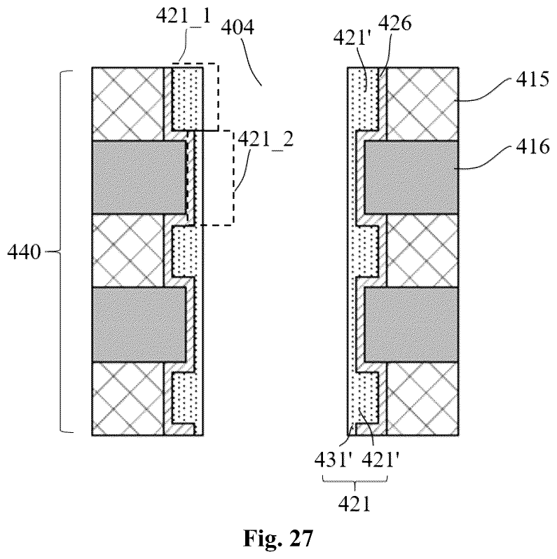

With reference to FIG. 27, in some example processes after the portion of the surface of the second dielectric layer 426 away from the material layers (e.g., the conductive layers 416) is exposed, a second blocking layer 431′ may be formed on the remaining portions of the first blocking layer 421′ and the exposed portion of the surface of the second dielectric layer 426 away from the material layers (e.g., the conductive layers 416). The processes for forming the second blocking layer 431′ include, for example, an ALD deposition process.

In some cases, the surface of second blocking layer 431′ away from the second dielectric layer 426 is even. when the surface of the second blocking layer 431′ away from the second dielectric layer 426 has a profile of cylinder or taper, the even surface of the second blocking layer 431′ away from the second dielectric layer 426 may be considered as the above-mentioned cylinder or taper shaped surface being a smooth surface, which should be regarded as being smooth with errors within a tolerant range instead of being absolutely smooth (for example, as a surface without any obvious depression). As one example, the remaining parts of the first blocking layer 421′ and the second blocking layer 431′ form the blocking layer 421 together.

In accordance with the example processes for forming the blocking layer 421 as shown in FIGS. 26 and 27, the first blocking layer 421′ may be formed using a CVD process, which has low cost and relatively higher deposition speed, while the second blocking layer 431′ may be formed using an ALD process. Using the processing above, the quality of the thin film deposition may be guaranteed while taking economic effects into account.

With reference to FIG. 25 or 27, in some examples, the blocking layer 421 includes, for example, the first blocking portions 421_1 on the surface of the second dielectric layer 426 away from the first dielectric layers 415 and the second blocking portions 421_2 on surface of the second dielectric layer 426 away from the material layers (e.g., the conductive layers 416). In some cases, the first blocking portions 421_1 are surrounded by, for example, the first dielectric layers 415 along the circumference of the channel hole 404 and the second blocking portions 421_2 are surrounded by, for example, the material layers (e.g., the conductive layers 416) along the circumference of the channel hole 404. As one example, the portions of the second dielectric layer 426 surrounded by the first dielectric layers 415 may have a thickness in the direction parallel with the first dielectric layers 415, which, for example, is less than that of the first blocking portions 421_1.

In some example processes after forming the blocking layer 421 as shown in FIG. 27, a storage layer 422 and a tunneling layer 423 may be sequentially formed over the surface of the blocking layer 421, as shown in FIG. 17, using one or more thin film deposition processes such as CVD, PVD, ALD or any combination thereof. During operations of the 3D memory, the storage layer 422 may be used to, for example, trap charges from the channel layer 424 to be described below. The materials used for the storage layer 422 may include charge trapping materials including, for example, silicon nitride, silicon oxynitride, silicon or any combination thereof. The tunneling layer 423 may include dielectric materials through which tunneling may occur under an appropriate bias. The materials used for the tunneling layer 423 may include silicon oxide, silicon oxynitride or any combination thereof.

Returning to FIG. 18, as one example, a channel layer 424 may be formed over the surface of the tunneling layer 423 using one or more thin film deposition processes such as CVD, PVD, ALD or any combination thereof. During operations of the 3D memory, the charges transported from the channel layer 424 may tunnel via the tunneling layer into the storage layer 422. The materials used for the channel layer 424 include, for example, polysilicon. In some cases, the channel layer 424 may be doped for conductivity (e.g., N-type or P-type doped for conductivity) to improve its conductivity.

With continued reference to FIG. 18, as one example, a dielectric core 425 may be formed in the space defined by the channel layer 424 using one or more thin film deposition processes such as CVD, PVD, ALD or any combination thereof. The materials used for the dielectric core 425 include, for example, silicon oxide.

In some example processes after forming the channel structure 420, a conductive plug (not shown) may be formed at the top of the channel structure 420 away from the substrate and in contact with the channel layer 424. In some examples, the conductive plug may serve as a part of the drain of the corresponding memory cell string 308 (FIG. 2). The materials used for the conductive plug include, for example, polysilicon.

In accordance with the method 300 in some implementations of the disclosure, for example, in accordance with the example methods as shown in FIGS. 18-27, the channel structure 420 may be formed after replacing the first sacrificial layers 416′ with the conductive layers 416 to avoid damage to the second dielectric layer 426 that could occur if the channel structure 420 is first formed and then the first sacrificial layers 416′ are replaced with the conductive layers 416.

In some examples, the method 300 of fabricating a 3D memory further includes some operations for forming peripheral circuits (not shown) and bonding the peripheral circuits and the memory array 301 together. In some examples, the peripheral circuits may be formed on a different substrate than the substrate described above, and may optionally include, for example, high-voltage devices for controlling high-voltage signals and/or low-voltage devices for improving reading/writing speed. Optionally, the above-mentioned high-voltage devices and/or low-voltage devices may include, for example, MOS transistors (not shown). Optionally, an interconnect layer may be formed over the peripheral circuits for interconnection with the memory array.

In some cases, the peripheral circuits and the memory array 301 may be hybrid-bonded together in a face-to-face manner. The peripheral circuits and the memory array 301 have their respective interconnect layers in corresponding contact with each other at the bonding interface and thereby are electrically connected. During operations of the 3D memory, by electrically connecting the memory array 301 and the peripheral circuits, the peripheral circuits may control the memory array 301.

Since the structures and features as discussed above with respect to the 3D memory 400 may be fully or partially applicable to serve as the same or similar structures and features as discussed above with respect to the method 300 herein, no repetition will be made to the related or similar description.

In the forgoing section of Detailed Description, objects, technical solutions and beneficial effects of the disclosure have been fully illustrated. It is to be appreciated that the above description is only specific implementations of the disclosure and will in no way limit the disclosure. Any modifications, equivalent substitutions and improvements made within the spirit and principle of the disclosure will fall in the protect scope claimed by the appended claims.

1. A three-dimensional (3D) memory, comprising:
a stack including alternately stacked first dielectric layers and conductive layers; and
a channel structure extending through the stack and including a second dielectric layer and a blocking layer disposed in this order from outside to inside, wherein the second dielectric layer has a dielectric constant greater than or equal to 3.9.

2. The 3D memory of claim 1, wherein the blocking layer further comprises:
first blocking portions located on a surface of the second dielectric layer away from the first dielectric layers; and
second blocking portions located on a surface of the second dielectric layer away from the conductive layers,
wherein the first blocking portions have a thickness larger than that of the second blocking portions in the direction parallel with the first dielectric layers.

3. The 3D memory of claim 1, wherein a surface of the blocking layer away from the second dielectric layer is even.

4. The 3D memory of claim 2, wherein surfaces of the first blocking portions away from the second dielectric layer are flush with surfaces of the second blocking portions away from the second dielectric layer.

5. The 3D memory of claim 1, wherein the second dielectric layer further comprises:
first dielectric portions extending in the direction of thickness of the stack; and
second dielectric portions extending in the direction parallel with the first dielectric layers, wherein the first dielectric portions are in contact with respective second dielectric portions.

6. The 3D memory of claim 5, wherein the first blocking portions have a thickness larger than that of the first dielectric portions in the direction parallel with the first dielectric layers.

7. The 3D memory of claim 1, wherein the channel structure further comprises a storage layer, a tunneling layer and a channel layer disposed in this order from outside to inside with the storage layer being located on a surface of the blocking layer away from the second dielectric layer.

8. The 3D memory of claim 1, wherein the dielectric constant of the second dielectric layer is greater than or equal to 10.

9. A memory system, comprising:
the 3D memory of claim 1; and
a memory controller coupled to the 3D memory and configured to control the 3D memory.

10. The memory system of claim 9, comprising a solid state drive or a memory card.

11. A method of fabricating a three-dimensional (3D) memory, comprising:
forming a channel hole in a stack including alternately stacked first dielectric layers and material layers; and
forming a second dielectric layer and a blocking layer sequentially over an inner wall of the channel hole, wherein the second dielectric layer has a dielectric constant greater than or equal to 3.9.

12. The method of claim 11, wherein the forming the channel hole in the stack further comprises:
forming a first channel hole extending through the stack; and
removing a portion of the first dielectric layers along the first channel hole to form the channel hole.

13. The method of claim 11, wherein the forming the blocking layer further comprises:
forming a first blocking layer over a surface of the second dielectric layer; and
removing a portion of the first blocking layer away from the material layers to form the blocking layer, wherein a surface of the blocking layer away from the second dielectric layer is even.

14. The method of claim 11, wherein the forming the blocking layer further comprises:
forming a second blocking layer over a surface of the second dielectric layer;
removing a portion of the second blocking layer away from the material layers to expose a surface of the second dielectric layer away from the material layers; and
forming a third blocking layer over remaining portions of the second blocking layer and the exposed surface of the second dielectric layer,
wherein a surface of the third blocking layer away from the second dielectric layer is even, and the remaining portions of the second blocking layer and the third blocking layer form the blocking layer together.

15. The method of claim 11, wherein the material layers comprise first sacrificial layers, the method further comprising:
removing the first sacrificial layers after forming the blocking layer; and
forming conductive layers in spaces formed by removing the first sacrificial layers.

16. The method of claim 11, wherein the material layers comprise conductive layers, wherein the forming the stack further comprises:
forming a second channel hole in a stack structure including the first dielectric layers and first sacrificial layers alternately stacked;
removing the first sacrificial layers; and
forming the conductive layers in spaces formed by removing the first sacrificial layers.

17. The method of claim 16, wherein the forming the stack further comprises:
filling a second sacrificial layer into the second channel hole before removing the first sacrificial layers; and
removing the second sacrificial layer after forming the conductive layers.

18. The method of claim 17, wherein the forming the channel hole in the stack further comprises:
removing a portion of the first dielectric layers through the second channel hole to form the channel hole.

19. The method of claim 11, further comprising:
forming a storage layer, a tunneling layer and a channel layer sequentially over a surface of the blocking layer; and
forming a dielectric core in a space defined by the channel layer.
